(19) United States
(12) Patent Application Publication
(10) Pub. No.: US 2023/0115834 A1
(43) Pub. Date: Apr. 13, 2023

(54) PIEZOELECTRIC DEVICE

(71) Applicant: Murata Manufacturing Co., Ltd., Nagaokakyo-shi (JP)

(72) Inventors: Yuzo KISHI, Nagaokakyo-shi (JP); Yutaka KISHIMOTO, Nagaokakyo-shi (JP); Shinsuke IKEUCHI, Nagaokakyo-shi (JP)

(21) Appl. No.: 18/079,479

(22) Filed: Dec. 12, 2022

Related U.S. Application Data
(63) Continuation of application No. PCT/JP2021/020204, filed on May 27, 2021.

(30) Foreign Application Priority Data
Jun. 11, 2020 (JP) 2020-101385

(51) Int. Cl. H10N 30/20; H10N 30/01; H10N 30/87; H10N 30/00; H10N 30/85

(52) U.S. Cl. CPC H01L 41/0973; H01L 41/18; H01L 41/22; H01L 41/0471; H01L 41/0815

(57) ABSTRACT

A piezoelectric device includes a base and a laminated portion. The laminated portion includes, at least above a recess, a piezoelectric layer, a pair of electrode layers to apply a voltage to the piezoelectric layer, and a membrane covering the recess. The membrane includes a piezoelectric membrane, in the piezoelectric layer, that swells on at least one of a side of the recess and a side opposite to the side of the recess.

### CROSS REFERENCE TO RELATED APPLICATIONS

This application claims the benefit of priority to Japanese Patent Application No. 2020-101385 filed on Jun. 11, 2020 and is a Continuation Application of PCT Application No. PCT/JP2021/020204 filed on May 27, 2021. The entire contents of each application are hereby incorporated herein by reference.

### BACKGROUND OF THE INVENTION

### 1. Field of the Invention

The present invention relates to a piezoelectric device.

### 2. Description of the Related Art

As a related art document describing a configuration of a piezoelectric device, for example, there is “Modeling, Fabrication, and Characterization of Piezoelectric Micromachined Ultrasonic Transducer Arrays Based on Cavity SOI Wafers” Y. Lu et al., Journal of Microelectromechanical Systems, vol. 24, no. 4, August 2015, pp. 1143-1149. The piezoelectric device described in the aforementioned related art document includes a silicon on insulator (SOI) substrate having a cavity, a piezoelectric layer disposed at least above the cavity, an upper electrode layer provided on an upper side of the piezoelectric layer, and a lower electrode layer provided on a side opposite to the upper electrode layer with the piezoelectric layer interposed therebetween.

In the piezoelectric device described in the aforementioned related art document, when the piezoelectric layer vibrates as a voltage is applied to a portion between the upper electrode layer and the lower electrode layer, since a portion of the piezoelectric layer that vibrates has a flat plate shape, the vibration propagates along the peripheral edge of the piezoelectric device and is attenuated, and the excitation efficiency and the Q factor of the piezoelectric device decrease.

### SUMMARY OF THE INVENTION

Preferred embodiments of the present invention provide piezoelectric devices each having a high excitation efficiency and Q factor.

A piezoelectric device according to a preferred embodiment of the present invention includes a base and a laminated portion. The base includes a first main surface and a second main surface on a side opposite to the first main surface and includes a recess on the first main surface. The laminated portion is laminated on a side of the first main surface of the base and covers the recess from above. The laminated portion includes, at least above the recess, a piezoelectric layer and a pair of electrode layers applying a voltage to the piezoelectric layer, and includes a membrane covering the recess. The membrane includes a piezoelectric membrane, in the piezoelectric layer, that swells on at least one of a side of the recess and a side opposite to the side of the recess.

According to preferred embodiments of the present invention, the excitation frequency and the Q factor of a piezoelectric device can be increased.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a sectional view illustrating a configuration of a piezoelectric device according to a first preferred embodiment of the present invention.

FIG. 2 is a sectional view illustrating a state in which a lower electrode layer is provided on a lower surface of a piezoelectric layer in a method for manufacturing the piezoelectric device according to the first preferred embodiment of the present invention.

FIG. 3 is a sectional view illustrating a state in which an intermediate layer is provided on a lower surface of each of the lower electrode layer and the piezoelectric layer in a method for manufacturing the piezoelectric device according to the first preferred embodiment of the present invention.

FIG. 4 is a sectional view illustrating a state in which a lower surface of the intermediate layer is made flat in a method for manufacturing the piezoelectric device according to the first preferred embodiment of the present invention.

FIG. 5 is a sectional view illustrating a state before a recess is formed in a base in a method for manufacturing the piezoelectric device according to the first preferred embodiment of the present invention.

FIG. 6 is a sectional view illustrating a state in which the recess is formed in the base in a method for manufacturing the piezoelectric device according to the first preferred embodiment of the present invention.

FIG. 7 is a sectional view illustrating a state in which the base is being bonded to a plurality of layers illustrated in FIG. 4 in the method for manufacturing the piezoelectric device according to the first preferred embodiment of the present invention.

FIG. 8 is a sectional view illustrating a state in which the base has been bonded to the lower surface of the intermediate layer in a method for manufacturing the piezoelectric device according to the first preferred embodiment of the present invention.

FIG. 9 is a sectional view illustrating a state in which thickness processing is performed on an upper surface of the piezoelectric layer in a method for manufacturing the piezoelectric device according to the first preferred embodiment of the present invention.

FIG. 10 is a sectional view illustrating a state in which an upper electrode layer is provided on the upper surface of the piezoelectric layer in a method for manufacturing the piezoelectric device according to the first preferred embodiment of the present invention.

FIG. 11 is a sectional view illustrating a configuration of a piezoelectric device according to a first modification of the first preferred embodiment of the present invention.

FIG. 12 is a sectional view illustrating a configuration of a piezoelectric device according to a second modification of the first preferred embodiment of the present invention.

FIG. 13 is a sectional view illustrating a configuration of a piezoelectric device according to a third modification of the first preferred embodiment of the present invention.

FIG. 14 is a sectional view illustrating a configuration of a piezoelectric device according to a fourth modification of the first preferred embodiment of the present invention.

FIG. 15 is a sectional view illustrating a configuration of a piezoelectric device according to a second preferred embodiment of the present invention.

FIG. 16 is a sectional view illustrating a state before a recess is formed in a base in a method for manufacturing the piezoelectric device according to the second preferred embodiment of the present invention.

FIG. 17 is a sectional view illustrating a state in which the recess is formed in the base in a method for manufacturing the piezoelectric device according to the second preferred embodiment of the present invention.

FIG. 18 is a sectional view illustrating a state in which the base is subjected to thermal oxidation in a method for manufacturing the piezoelectric device according to the second preferred embodiment of the present invention.

FIG. 19 is a sectional view illustrating a state in which the base is being bonded to a lower electrode layer in a method for manufacturing the piezoelectric device according to the second preferred embodiment of the present invention.

FIG. 20 is a sectional view illustrating a state in which the lower electrode layer is being bonded to a piezoelectric layer in a method for manufacturing the piezoelectric device according to the second preferred embodiment of the present invention.

FIG. 21 is a sectional view illustrating a state in which the piezoelectric layer has been bonded to an upper surface of the lower electrode layer in a method for manufacturing the piezoelectric device according to the second preferred embodiment of the present invention.

FIG. 22 is a sectional view illustrating a state in which thickness processing is performed on an upper surface of the piezoelectric layer in a method for manufacturing the piezoelectric device according to the second preferred embodiment of the present invention.

FIG. 23 is a sectional view illustrating a state in which an upper electrode layer is provided on the upper surface of the piezoelectric layer in a method for manufacturing the piezoelectric device according to the second preferred embodiment of the present invention.

FIG. 24 is a sectional view illustrating a configuration of a piezoelectric device according to a first modification of the second preferred embodiment of the present invention.

FIG. 25 is a sectional view illustrating a configuration of a piezoelectric device according to a second modification of the second preferred embodiment of the present invention.

FIG. 26 is a sectional view illustrating a configuration of a piezoelectric device according to a third modification of the second preferred embodiment of the present invention.

FIG. 27 is a sectional view illustrating a configuration of a piezoelectric device according to a fourth modification of the second preferred embodiment of the present invention.

### DETAILED DESCRIPTION OF THE PREFERRED EMBODIMENTS

Hereinafter, piezoelectric devices according to preferred embodiments of the present invention will be described with reference to the drawings. In the drawings, the same or corresponding elements and portions are denoted by the same reference numerals and duplicated descriptions will be omitted.

### First Preferred Embodiment

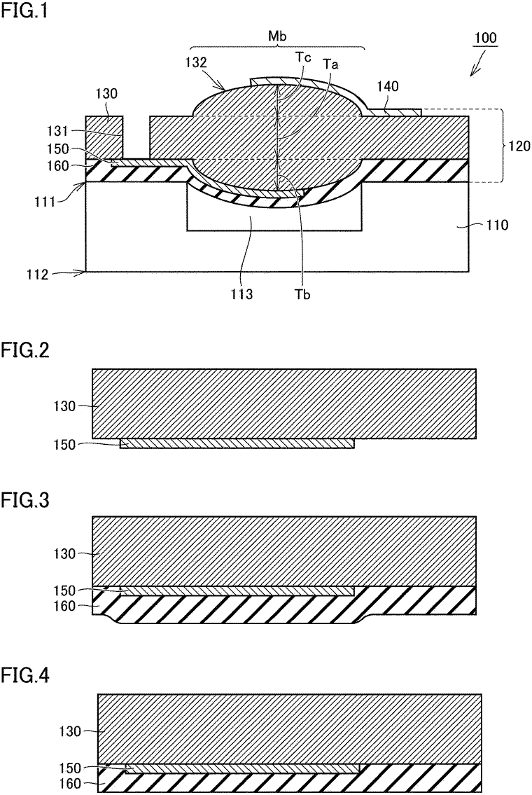

FIG. 1 is a sectional view illustrating a configuration of a piezoelectric device according a first preferred embodiment of the present invention. As illustrated in FIG. 1, a piezoelectric device 100 according to the first preferred embodiment of the present invention includes a base 110 and a laminated portion 120.

The base 110 includes a first main surface 111 and a second main surface 112 located on a side opposite to the first main surface 111. The base 110 includes a recess 113 in the first main surface 111.

The recess 113 is covered, from above, with the laminated portion 120 that is laminated on the first main surface 111 side of the base 110. In the present preferred embodiment, the inside of the recess 113 is a sealed space.

In the piezoelectric device 100 according to the present preferred embodiment, the pressure inside the recess 113 is a negative pressure. The pressure inside the recess 113 may be atmospheric pressure or a positive pressure.

In the present preferred embodiment, the base 110 is made of Si, for example. However, the material of the base 110 is not limited to Si.

The laminated portion 120 includes a piezoelectric layer 130 and a pair of electrode layers. The pair of electrode layers apply a voltage to the piezoelectric layer 130. In the present preferred embodiment, the pair of electrode layers include an upper electrode layer 140 and a lower electrode layer 150. While the lower electrode layer 150 is not provided, the upper electrode layer 140 may define a pair of electrode layers arranged so as to be spaced apart from each other and between which a voltage is applied. The laminated portion 120 further includes an intermediate layer 160.

The laminated portion 120 includes a membrane Mb that covers the recess 113. The membrane Mb is a portion located in the laminated portion 120 on an inner side of an opening end of the recess 113, when viewed in a direction orthogonal or substantially orthogonal to the first main surface 111. In the membrane Mb, a slit extending through the membrane Mb in an up-down direction may be provided.

The piezoelectric layer 130 is located on an upper side of the base 110. A portion of the piezoelectric layer 130 is located above the recess 113. The piezoelectric layer 130 includes a piezoelectric membrane 132 that covers the recess 113. The piezoelectric membrane 132 defines a portion of the membrane Mb.

The piezoelectric membrane 132 swells on at least one of the recess 113 side and a side opposite to the recess 113 side. In the present preferred embodiment, the piezoelectric membrane 132 swells on both of the recess 113 side and the side opposite to the recess 113 side.

A surface of a portion, of the piezoelectric membrane 132, swelling on the recess 113 side is a curved surface. A surface of a portion, of the piezoelectric membrane 132, swelling on the side opposite to the recess 113 side is a curved surface. The surface of the portion, of the piezoelectric membrane 132, swelling on the recess 113 side may be a conical surface. The surface of the portion, of the piezoelectric membrane 132, swelling on the side opposite to the recess 113 side may be a conical surface.

The piezoelectric layer 130 includes a hole portion 131. The hole portion 131 extends through the piezoelectric layer 130 in the up-down direction. In the present preferred embodiment, the hole portion 131 is located above the first main surface 111 of the base 110 and is not located above the recess 113. Portions excluding the hole portion 131 and the piezoelectric membrane 132 in the piezoelectric layer 130 have a flat plate shape.

As illustrated in FIG. 1, in the piezoelectric layer 130, a portion having a flat plate shape has a thickness dimension Ta. In the present preferred embodiment, a portion, of the piezoelectric membrane 132, swelling on the recess 113 side swells the most at a position on a center of the recess 113 when viewed in the direction orthogonal or substantially orthogonal to the first main surface 111 and has a swelling height dimension Tb. A portion, of the piezoelectric membrane 132, swelling on the side opposite to the recess 113 side swells the most at a position at the center or approximate center of the recess 113 when viewed in the direction orthogonal or substantially orthogonal to the first main surface 111 and has a swelling height dimension Tc.

As the swelling height dimension (Tb + Tc) of the piezoelectric membrane 132 increases, the thickness dimension (Ta + Tb + Tc) of the piezoelectric membrane 132 increases.

The piezoelectric layer 130 is made of a piezoelectric single-crystal body. Specifically, the piezoelectric layer 130 is made of lithium tantalate or lithium niobate, for example. A polarization state of the piezoelectric layer 130 made of lithium tantalate or lithium niobate is uniform or substantially uniform.

The upper electrode layer 140 is disposed on an upper side of the piezoelectric layer 130. A portion of the upper electrode layer 140 is located above the recess 113. In the present preferred embodiment, the upper electrode layer 140 is disposed on an upper side of a portion of the piezoelectric layer 130. The upper electrode layer 140 is made of, for example, metal such as Al or Pt. A close-contact layer made of, for example, Ti or the like may be disposed between the upper electrode layer 140 and the piezoelectric layer 130.

A portion of the lower electrode layer 150 faces a portion of the upper electrode layer 140 with the piezoelectric membrane 132 interposed therebetween. Another portion of the lower electrode layer 150 is located below the hole portion 131 in the piezoelectric layer 130. In the present preferred embodiment, the lower electrode layer 150 covers the hole portion 131 of the piezoelectric layer 130 from below. In the hole portion 131, extended wiring connected onto the lower electrode layer 150 may be provided. The lower electrode layer 150 is made of, for example, metal such as Al or Pt.

The lower electrode layer 150 may cover the lower portion of the hole portion 131 of the piezoelectric layer 130 with a close-contact layer interposed therebetween. The material of the close-contract layer is not particularly limited as long as the material is conductive and adhesive. The close-contact layer is made of, for example, Ti, Cr, Ni, or NiCr.

The intermediate layer 160 is laminated so as to cover the lower electrode layer 150 from below. In the present preferred embodiment, the intermediate layer 160 is in contact with each of the lower surface of the lower electrode layer 150 and a portion of the lower surface of the piezoelectric layer 130 not covered with the lower electrode layer 150. A portion of the lower surface of the intermediate layer 160 is in contact with the first main surface 111 of the base 110.

A portion of the intermediate layer 160 covering the recess 113 is curved and projects on the second main surface 112 side. A portion of the intermediate layer 160 not covering the recess 113 has a flat plate shape. The portion of the intermediate layer 160 not covering the recess 113 and the base 110 are directly connected to each other. The portion of the intermediate layer 160 not covering the recess 113 and the base 110 do not have to be directly connected to each other. The portion of the intermediate layer 160 not covering the recess 113 and the base 110 may be connected to each other with a metal layer interposed therebetween.

In the present preferred embodiment, the intermediate layer 160 is made of, for example, SiO₂. The material of the intermediate layer 160 is not limited to SiO₂ and any material may be used as long as it is an insulating material. For example, the intermediate layer 160 may be made of an organic material having an electric insulating property and a thermal insulating property.

As described above, in the present preferred embodiment, the laminated portion 120 includes, at least above the recess 113, the piezoelectric layer 130, the upper electrode layer 140, the lower electrode layer 150, and the intermediate layer 160.

In the present preferred embodiment, when viewed in the direction orthogonal or substantially orthogonal to the first main surface 111, the external shape of the recess 113 is rectangular or substantially rectangular. However, when viewed in the direction orthogonal or substantially orthogonal to the first main surface 111, the external shape of the recess 113 is not limited to being rectangular or substantially rectangular, and may be a polygonal other than rectangular or substantially rectangular, or may be a circular or substantially circular.

Hereinafter, a non-limiting example of a method for manufacturing the piezoelectric device 100 according to the first preferred embodiment of the present invention will be described.

FIG. 2 is a sectional view illustrating a state in which the lower electrode layer is provided on the lower surface of the piezoelectric layer in the method for manufacturing the piezoelectric device according to the first preferred embodiment of the present invention. The thickness of the piezoelectric layer 130 during formation is greater than the final thickness of the piezoelectric layer 130 to be included in the piezoelectric device 100 according to the present preferred embodiment.

As illustrated in FIG. 2, the lower electrode layer 150 is provided on the lower surface of the piezoelectric layer 130 by, for example, a lift-off method, a plating method, an etching method, or the like.

FIG. 3 is a sectional view illustrating a state in which the intermediate layer is provided on the lower surface of each of the lower electrode layer and the piezoelectric layer in the method for manufacturing the piezoelectric device according to the first preferred embodiment of the present invention. As illustrated in FIG. 3, the intermediate layer 160 is provided on the lower surface of each of the lower electrode layer 150 and the piezoelectric layer 130 by, for example, a chemical vapor deposition (CVD) method, a physical vapor deposition (PVD) method, or the like.

FIG. 4 is a sectional view illustrating a state in which the lower surface of the intermediate layer is made flat in the method for manufacturing the piezoelectric device according to the first preferred embodiment of the present invention. As illustrated in FIG. 4, the lower surface of the intermediate layer 160 is made flat by, for example, chemical mechanical polishing (CMP) or the like.

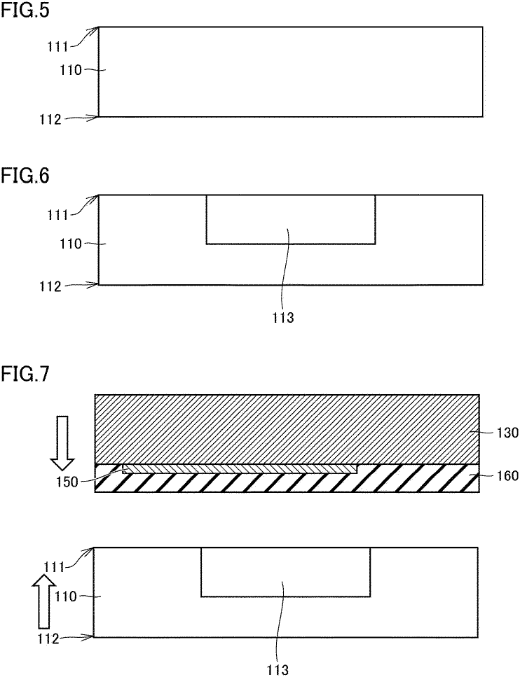

FIG. 5 is a sectional view illustrating a state before the recess is formed in the base in the method for manufacturing the piezoelectric device according to the first preferred embodiment of the present invention. FIG. 6 is a sectional view illustrating a state in which the recess is formed in the base in the method for manufacturing the piezoelectric device according to the first preferred embodiment of the present invention.

As illustrated in FIGS. 5 and 6, the recess 113 is formed in the base 110 by performing, for example, deep reactive-ion etching (DRIE) on the base 110 from the first main surface 111 side.

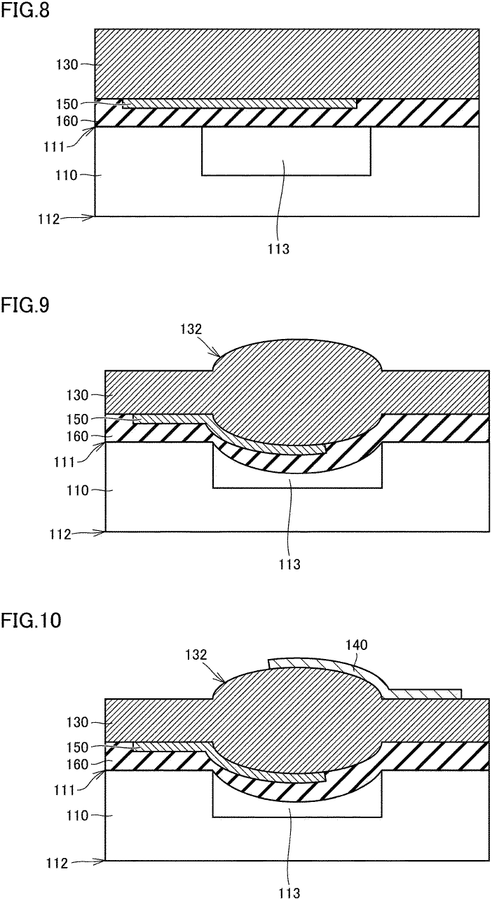

FIG. 7 is a sectional view illustrating a state in which the base is being bonded to the plurality of layers illustrated in FIG. 4 in the method for manufacturing the piezoelectric device according to the first preferred embodiment of the present invention. FIG. 8 is a sectional view illustrating a state in which the base has been bonded to the lower surface of the intermediate layer in the method for manufacturing the piezoelectric device according to the first preferred embodiment of the present invention.

As illustrated in FIGS. 7 and 8, the first main surface 111 of the base 110 is bonded to the lower surface of the intermediate layer 160 by, for example, surface activated bonding, atomic diffusion bonding, or the like. As a result, the inside of the recess 113 becomes a sealed space.

In the present preferred embodiment, in order to reduce or prevent intrusion of a foreign substance into the recess 113, the intermediate layer 160 and the base 110 are bonded under vacuum pressure. In this case, the above-described vacuum pressure may be any of, for example, low vacuum, medium vacuum, high vacuum, and ultra-high vacuum. Since the intermediate layer 160 and the base 110 are bonded in this manner, the pressure in the recess 113 becomes negative pressure. The atmosphere when the intermediate layer 160 and the base 110 are bonded is not limited to being under vacuum pressure. The intermediate layer 160 may be bonded to the base 110 under atmospheric pressure, or may be bonded to the base 110 under pressure higher than the atmospheric pressure.

FIG. 9 is a sectional view illustrating a state in which thickness processing is performed on an upper surface of the piezoelectric layer in the method for manufacturing the piezoelectric device according to the first preferred embodiment of the present invention. As illustrated in FIG. 9, by processing the upper surface of the piezoelectric layer 130 by, for example, grinding, polishing, chemical mechanical polishing (CMP), or the like, the piezoelectric layer 130 is made to have a desired thickness. A release layer may be formed by performing ion implantation on the upper surface side of the piezoelectric layer 130 in advance. In this case, before processing the upper surface of the piezoelectric layer 130 by, for example, grinding, polishing, CMP, or the like, the release layer is removed, such that the thickness of the piezoelectric layer 130 is easily adjusted.

In the present preferred embodiment, the piezoelectric membrane 132 is formed by making the piezoelectric layer 130 thin by, for example, grinding the upper surface of the piezoelectric layer 130. Specifically, the upper surface of the piezoelectric layer 130 is ground so as to form a portion, of the piezoelectric membrane 132, swelling on the side opposite to the recess 113 side. Since the pressure inside the recess 113 is negative pressure, as the upper surface of the piezoelectric layer 130 is ground, and the piezoelectric layer 130 becomes thinner, a portion of the piezoelectric layer 130 covering the recess 113 is curved, and a portion, of the piezoelectric membrane 132, swelling on the recess 113 side is formed.

FIG. 10 is a sectional view illustrating a state in which the upper electrode layer is provided on the upper surface of the piezoelectric layer in the method for manufacturing the piezoelectric device according to the first preferred embodiment of the present invention. As illustrated in FIG. 10, the upper electrode layer 140 is provided on a portion of the upper surface of the piezoelectric layer 130 by, for example, a lift-off method, a plating method, an etching method, or the like. In this manner, the laminated portion 120 is laminated on the first main surface 111 side of the base 110.

Finally, the hole portion 131 is provided on a portion of the upper surface of the piezoelectric layer 130 by, for example, a lift-off method, a plating method, an etching method, or the like.

By the above-described steps, the piezoelectric device 100 according to the first preferred embodiment of the present invention illustrated in FIG. 1 is manufactured.

As described above, in the piezoelectric device 100 according to the present preferred embodiment, since the piezoelectric membrane 132 swells on at least one of the recess 113 side and the side opposite to the recess 113 side, a propagation path of vibration of the piezoelectric membrane 132 is narrowed and reduced at a boundary between the portion in the piezoelectric layer 130 having a flat plate shape and the piezoelectric membrane 132, attenuation of the vibration due to propagation of the vibration along the peripheral edge of the piezoelectric device 100 can be reduced or prevented. As a result, the excitation efficiency and the Q factor of the piezoelectric device 100 can be increased.

In the piezoelectric device 100 according to the present preferred embodiment, the piezoelectric layer 130 is made of a piezoelectric single-crystal body. As a result, the polarization state of the piezoelectric layer 130 can be made uniform or substantially uniform, and the excitation characteristics of the piezoelectric device 100 can be improved.

In the piezoelectric device 100 according to the present preferred embodiment, the surface of the portion, of the piezoelectric membrane 132, swelling on the recess 113 side is a curved surface. As a result, stress concentration can be generated in advance at a boundary between the portion in the piezoelectric layer 130 having a flat plate shape and the piezoelectric membrane 132, and the amplitude of the stress generated at the boundary when the piezoelectric membrane 132 is excited can be reduced. As a result, the excitation characteristics of the piezoelectric device 100 can be improved.

In the piezoelectric device 100 according to the present preferred embodiment, as the swelling height dimension of the piezoelectric membrane 132 increases, the thickness dimension of the piezoelectric membrane 132 increases. Accordingly, in a longitudinal section of the piezoelectric membrane 132, about a virtual central line located on the center or approximate center of the recess 113, the symmetry of the shape of the piezoelectric membrane 132 can be improved. As a result, the excitation characteristics of the piezoelectric device 100 can be improved.

In the piezoelectric device 100 according to the present preferred embodiment, since the inside of the recess 113 is sealed, intrusion of a foreign substance into the recess 113 can be reduced or prevented.

In the piezoelectric device 100 according to the present preferred embodiment, since the pressure inside the recess 113 is negative pressure, by making the piezoelectric layer 130 thin, the piezoelectric membrane 132 can be easily swelled on the recess 113 side.

In the piezoelectric device 100 according to the present preferred embodiment, since the pressure inside the recess 113 is a vacuum, the swelling height Tb of the portion, of the piezoelectric membrane 132, swelling on the recess 113 side can be increased. As a result, the excitation efficiency and the Q factor of the piezoelectric device 100 can be effectively increased.

In the piezoelectric device 100 according to the present preferred embodiment, the intermediate layer 160 is laminated so as to cover the lower electrode layer 150 from below. As a result, since the lower surface of the lower electrode layer 150 is not exposed to the outside and the recess 113, deterioration of the lower electrode layer 150 can be reduced or prevented. The intermediate layer 160 is not necessarily provided. Alternatively, for example, a SiO₂ layer and a Si layer may be provided between the base 110 and the intermediate layer 160. In this case, the base 110, the SiO₂ layer, and the Si layer define an SOI substrate.

Hereinafter, modifications of the piezoelectric device according to the first preferred embodiment will be described.

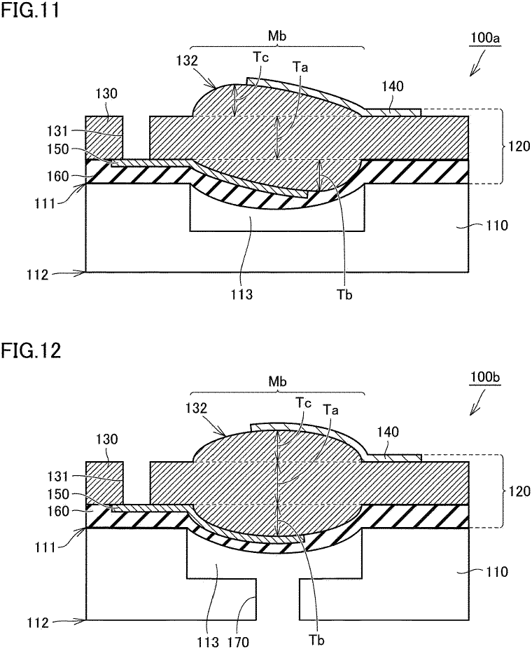

FIG. 11 is a sectional view illustrating a configuration of a piezoelectric device according to a first modification of the first preferred embodiment of the present invention. In FIG. 11, the piezoelectric device is illustrated in the sectional view the same as FIG. 1. As illustrated in FIG. 11, in a piezoelectric device 100a according to the first modification of the first preferred embodiment of the present invention, when viewed in the direction orthogonal or substantially orthogonal to the first main surface 111, a position of a portion, of the piezoelectric membrane 132, swelling the most on the recess 113 side and a position of a portion, of the piezoelectric membrane 132, swelling the most on the side opposite to the recess 113 side are located while being displaced from each other.

FIG. 12 is a sectional view illustrating a configuration of a piezoelectric device according to a second modification of the first preferred embodiment of the present invention. In FIG. 12, the piezoelectric device is illustrated in the sectional view the same as FIG. 1. As illustrated in FIG. 12, in a piezoelectric device 100b according to the second modification of the first preferred embodiment of the present invention, a hole 170 that extends from the bottom of the recess 113 to the second main surface 112 of the base 110 is provided in the base 110.

When viewed in the direction orthogonal or substantially orthogonal to the first main surface 111, the area of the hole 170 is smaller than the area of the membrane Mb. As a result, a significant decrease in the rigidity of the base 110 due to providing of the hole 170 can be reduced or prevented.

When viewed in the direction orthogonal or substantially orthogonal to the first main surface 111, the diameter of the hole 170 is, for example, equal to or less than about 140 µm. The hole 170 can be formed by, for example, DRIE or the like. As a result, intrusion of water or a foreign substance into the recess 113 from outside the piezoelectric device 100b through the hole 170 can be reduced or prevented. When viewed in the direction orthogonal or substantially orthogonal to the first main surface 111, the area of the hole 170 and the area of the membrane Mb may be the same or substantially the same.

FIG. 13 is a sectional view illustrating a configuration of a piezoelectric device according to a third modification of the first preferred embodiment of the present invention. In FIG. 13, the piezoelectric device is illustrated in the sectional view the same as FIG. 1. As illustrated in FIG. 13, in a piezoelectric device 100c according to the third modification of the first preferred embodiment of the present invention, the piezoelectric membrane 132 swells only on the recess 113 side. The upper surface of the piezoelectric membrane 132 is a flat surface.

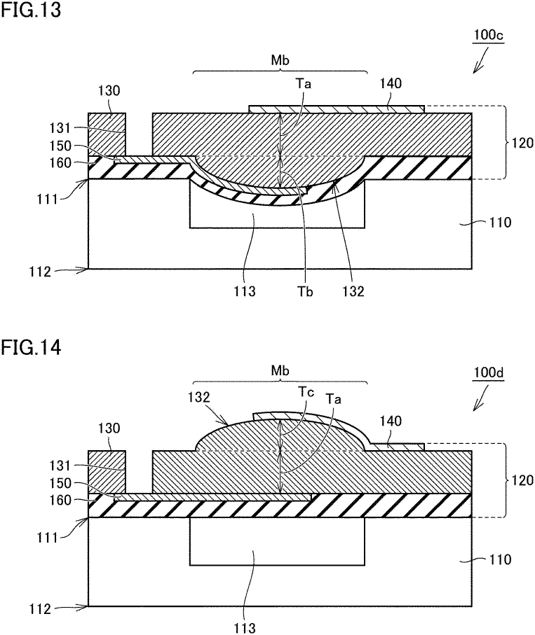

FIG. 14 is a sectional view illustrating a configuration of a piezoelectric device according to a fourth modification of the first preferred embodiment of the present invention. In FIG. 14, the piezoelectric device is illustrated in the sectional view the same as FIG. 1. As illustrated in FIG. 14, in a piezoelectric device 100d according to the fourth modification of the first preferred embodiment of the present invention, the piezoelectric membrane 132 swells only on the side opposite to the recess 113 side. The lower surface of the piezoelectric membrane 132 is a flat surface. The pressure inside the recess 113 is atmospheric pressure or positive pressure.

### Second Preferred Embodiment

Hereinafter, a piezoelectric device according to a second preferred embodiment of the present invention will be described with reference to the drawings. The piezoelectric device according to the second preferred embodiment of the present invention is different from the piezoelectric device 100 according to the first preferred embodiment of the present invention mainly in that the lower electrode layer includes, for example, Si as a main component. Therefore, descriptions of the configurations that are the same or substantially the same as the piezoelectric device 100 according to the first preferred embodiment of the present invention will not be repeated.

FIG. 15 is a sectional view illustrating a configuration of the piezoelectric device according to the second preferred embodiment of the present invention. As illustrated in FIG. 15, a piezoelectric device 200 according to the second preferred embodiment of the present preferred embodiment includes a base 210 and a laminated portion 220.

The base 210 includes a first main surface 211 and a second main surface 212 located on a side opposite to the first main surface 211. The base 210 includes a recess 213 that is provided on the first main surface 211.

The recess 213 is covered, from above, with the laminated portion 220 that is laminated on the first main surface 211 side of the base 210. In the present preferred embodiment, the inside of the recess 213 is a sealed space.

In the piezoelectric device 200 according to the present preferred embodiment, the pressure inside the recess 213 is negative pressure. The pressure inside the recess 213 may be atmospheric pressure or positive pressure.

In the present preferred embodiment, the base 210 includes a main body base 210a and a surface layer base 210b that covers a first main surface 211a of the main body base 210a. The surface layer base 210b also covers the inner surface of the recess 213. In the present preferred embodiment, for example, the main body base 210a is made of Si, and the surface layer base 210b is made of SiO₂. However, the material of the main body base 210a is not limited to Si, and the material of the surface layer base 210b is not limited to SiO₂.

The laminated portion 220 includes the piezoelectric layer 130 and a pair of electrode layers. The pair of electrode layers applies a voltage to the piezoelectric layer 130. In the present preferred embodiment, the pair of electrode layers include the upper electrode layer 140 and a lower electrode layer 250.

The laminated portion 220 includes the membrane Mb that covers the recess 213. The membrane Mb is a portion located in the laminated portion 220, when viewed in a direction orthogonal or substantially orthogonal to the first main surface 211, on an inner side of an opening end of the recess 213. In the membrane Mb, a slit extending through the membrane Mb in an up-down direction may be provided.

The piezoelectric layer 130 is located on an upper side of the base 210. A portion of the piezoelectric layer 130 is located above the recess 213. The piezoelectric layer 130 includes the piezoelectric membrane 132 that covers the recess 213. The piezoelectric membrane 132 defines a portion of the membrane Mb. The lower surface of the piezoelectric layer 130 is a flat surface.

The piezoelectric membrane 132 swells on the recess 213 side or a side opposite to the recess 213 side. In the present preferred embodiment, the piezoelectric membrane 132 swells on a side opposite to the recess 213 side. The surface of the portion, of the piezoelectric membrane 132, swelling on the side opposite to the recess 213 side is a curved surface. The surface of the portion, of the piezoelectric membrane 132, swelling on the side opposite to the recess 213 side may be a conical surface.

A portion of the lower electrode layer 250 faces a portion of the upper electrode layer 140 with the piezoelectric membrane 132 interposed therebetween. Another portion of the lower electrode layer 250 is located below the hole portion 131 in the piezoelectric layer 130. In the present preferred embodiment, the lower electrode layer 250 covers the hole portion 131 of the piezoelectric layer 130 from below. In the hole portion 131, extended wiring connected onto the lower electrode layer 250 may be provided.

A portion 252 of the lower electrode layer 250 covering the recess 213 is curved and projects on the second main surface 212 side. The upper surface of the lower electrode layer 250 is a flat surface. The portion of the lower electrode layer 250 not covering the recess 213 has a flat plate shape. The portion of the lower electrode layer 250 not covering the recess 213 and the base 210 are directly connected to each other.

As illustrated in FIG. 15, in the lower electrode layer 250, a portion having a flat plate shape has a thickness dimension Td. In the present preferred embodiment, the portion 252, of the lower electrode layer 250, swelling on the recess 213 side swells the most at a position on a center or approximate center of the recess 213 when viewed in the direction orthogonal or substantially orthogonal to the first main surface 211 and has a swelling height dimension Te. As the swelling height dimension Te of the lower electrode layer 250 increases, the thickness dimension (Td + Te) of the lower electrode layer 250 increases.

The lower electrode layer 250 includes, for example, Si as a main component. In the present preferred embodiment, the lower electrode layer 250 includes, for example, single crystal Si as a main component. Specifically, the lower electrode layer 250 is made of, for example, single crystal Si doped with an element that reduces the electric resistivity of the lower electrode layer 250.

The single crystal Si is doped with, for example, B, Al, Ga, P, As, Sb, or the like. In the present preferred embodiment, the electric resistivity of the material of the lower electrode layer 250 is preferably low, and, specifically, is preferably equal to or less than about 20 mΩ-cm, for example.

The lower electrode layer 250 is bonded to the piezoelectric layer 130 by, for example, surface activated bonding, atomic diffusion bonding, or the like. In the present preferred embodiment, since the piezoelectric layer 130 is made of a piezoelectric single-crystal body, and the lower electrode layer 250 includes single crystal Si as a main component, the piezoelectric device 200 has good electromechanical conversion efficiency.

As described above, in the present preferred embodiment, the laminated portion 220 includes, at least above the recess 213, the piezoelectric layer 130, the upper electrode layer 140, and the lower electrode layer 250.

In the present preferred embodiment, when viewed in the direction orthogonal or substantially orthogonal to the first main surface 211, the external shape of the recess 213 is rectangular or substantially rectangular. However, when viewed in the direction orthogonal or substantially orthogonal to the first main surface 211, the external shape of the recess 213 is not limited to being rectangular or substantially rectangular, and may be, for example, polygonal other than rectangular or substantially rectangular, or may be circular or substantially circular.

Hereinafter, a non-limiting example of a method for manufacturing the piezoelectric device 200 according to the second preferred embodiment of the present invention will be described.

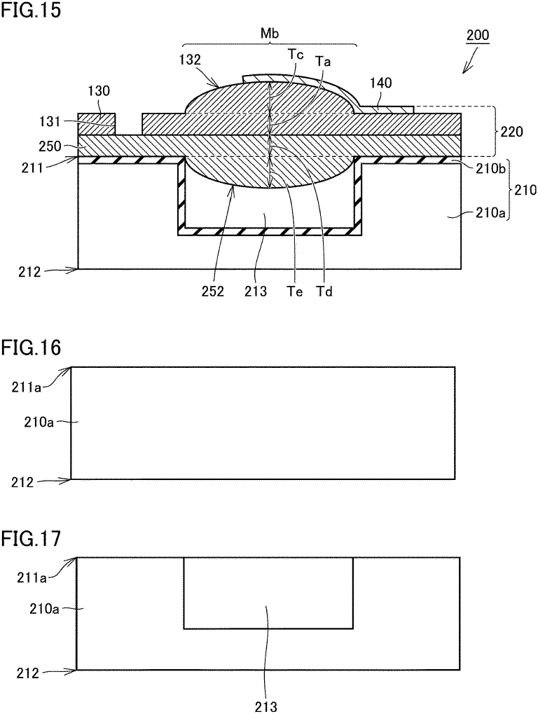

FIG. 16 is a sectional view illustrating a state before the recess is formed in the base in the method for manufacturing the piezoelectric device according to the second preferred embodiment of the present invention. FIG. 17 is a sectional view illustrating a state in which the recess is formed in the base in the method for manufacturing the piezoelectric device according to the second preferred embodiment of the present invention.

As illustrated in FIGS. 16 and 17, the recess 213 is formed in the main body base 210a by performing, for example, deep reactive-ion etching on the main body base 210a from the first main surface 211a side.

FIG. 18 is a sectional view illustrating a state in which the base is subjected to thermal oxidation in the method for manufacturing the piezoelectric device according to the second preferred embodiment of the present invention. As illustrated in FIG. 18, each of the first main surface 211a of the main body base 210a and the inner surface of the recess 213 is subjected to thermal oxidization. As a result, the surface layer base 210b that covers each of the first main surface 211a of the main body base 210a and the inner surface of the recess 213 is formed.

As described above, the base 210 includes the main body base 210a and the surface layer base 210b. The base 210 includes the first main surface 211 and the second main surface 212 located on a side opposite to the first main surface 211.

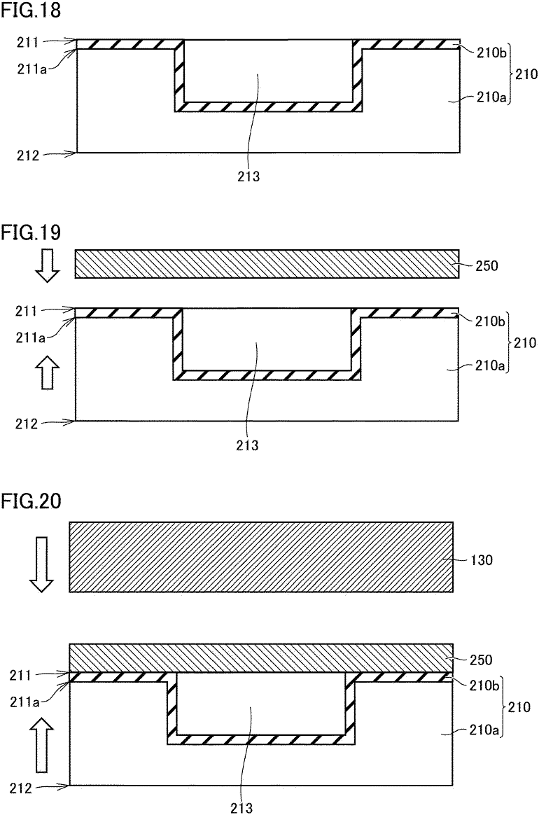

FIG. 19 is a sectional view illustrating a state in which the base is being bonded to the lower electrode layer in the method for manufacturing the piezoelectric device according to the second preferred embodiment of the present invention. As illustrated in FIG. 19, the first main surface 211 of the base 210 is being bonded to the lower surface of the lower electrode layer 250 by, for example, surface activated bonding, atomic diffusion bonding, or the like. As a result, the inside of the recess 213 becomes a sealed space.

In the present preferred embodiment, in order to reduce or prevent intrusion of a foreign substance into the recess 213, the lower electrode layer 250 and the base 210 are bonded under vacuum pressure. In this case, the above-described vacuum pressure may be, for example, any of low vacuum, medium vacuum, high vacuum, and ultra-high vacuum. Since the lower electrode layer 250 and the base 210 are bonded in this manner, the pressure in the recess 213 becomes negative pressure. The atmosphere when the lower electrode layer 250 and the base 210 are bonded is not limited to being under vacuum pressure. The lower electrode layer 250 may be bonded to the base 210 under atmospheric pressure, or may be bonded to the base 210 under pressure higher than the atmospheric pressure.

FIG. 20 is a sectional view illustrating a state in which the lower electrode layer is being bonded to the piezoelectric layer in the method for manufacturing the piezoelectric device according to the second preferred embodiment of the present invention. FIG. 21 is a sectional view illustrating a state in which the piezoelectric layer has been bonded to the upper surface of the lower electrode layer in the method for manufacturing the piezoelectric device according to the second preferred embodiment of the present invention.

As illustrated in FIGS. 20 and 21, the lower surface of the piezoelectric layer 130 is bonded to the upper surface of the lower electrode layer 250 by, for example, surface activated bonding, atomic diffusion bonding, or the like.

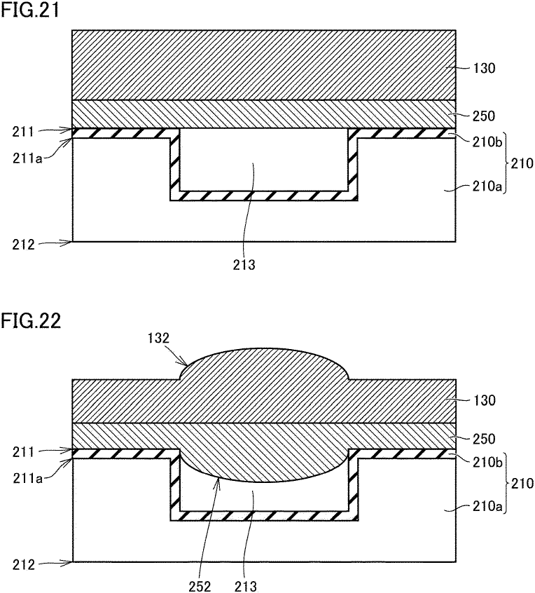

FIG. 22 is a sectional view illustrating a state in which thickness processing is performed on an upper surface of the piezoelectric layer in the method for manufacturing the piezoelectric device according to the second preferred embodiment of the present invention. As illustrated in FIG. 22, by processing the upper surface of the piezoelectric layer 130 by, for example, grinding, polishing, CMP, or the like, the piezoelectric layer 130 is made to have a desired thickness. A release layer may be formed by performing, for example, ion implantation on the upper surface side of the piezoelectric layer 130 in advance. In this case, before processing the upper surface of the piezoelectric layer 130 by, for example, grinding, polishing, CMP, or the like, the release layer is removed, such that the thickness of the piezoelectric layer 130 is easily adjusted.

In the present preferred embodiment, the piezoelectric membrane 132 is formed by making the piezoelectric layer 130 thin by, for example, grinding the upper surface of the piezoelectric layer 130. Specifically, the upper surface of the piezoelectric layer 130 is ground so as to form a portion, of the piezoelectric membrane 132, swelling on the side opposite to the recess 213 side. Since the pressure inside the recess 213 is negative pressure, as the upper surface of the piezoelectric layer 130 is ground, and the piezoelectric layer 130 becomes thinner, the portion 252 of the lower electrode layer 250 covering the recess 213 is curved and swells on the recess 213 side.

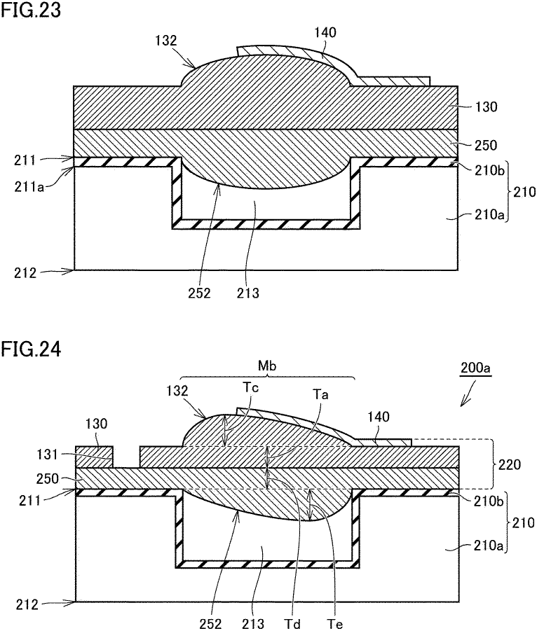

FIG. 23 is a sectional view illustrating a state in which the upper electrode layer is provided on the upper surface of the piezoelectric layer in the method for manufacturing the piezoelectric device according to the second preferred embodiment of the present invention. As illustrated in FIG. 23, the upper electrode layer 140 is provided on a portion of the upper surface of the piezoelectric layer 130 by, for example, a lift-off method, a plating method, an etching method, or the like. In this manner, the laminated portion 220 is laminated on the first main surface 211 side of the base 210.

Finally, the hole portion 131 is provided on a portion of the upper surface of the piezoelectric layer 130 by, for example, a lift-off method, a plating method, an etching method, or the like.

By the above-described steps, the piezoelectric device 200 according to the second preferred embodiment of the present invention illustrated in FIG. 15 is manufactured.

As described above, in the piezoelectric device 200 according to the present preferred embodiment, since the piezoelectric membrane 132 swells on the side opposite to the recess 213 side, a propagation path of vibration of the piezoelectric membrane 132 is narrowed and reduced at a boundary between the portion in the piezoelectric layer 130 having a flat plate shape and the piezoelectric membrane 132, attenuation of the vibration due to propagation of the vibration along the peripheral edge of the piezoelectric device 200 can be reduced or prevented. As a result, the excitation efficiency and the Q factor of the piezoelectric device 200 can be increased.

In the piezoelectric device 200 according to the present preferred embodiment, since the lower electrode layer 250 is made of, for example, Si having a low electric resistivity, formation of the intermediate layer 160 in the first preferred embodiment illustrated in FIG. 3 and, for example, CMP performed on the lower surface of the intermediate layer 160 in the first preferred embodiment illustrated in FIG. 4 can be unnecessary.

Hereinafter, modifications of the piezoelectric device according to the second preferred embodiment of the present invention will be described.

FIG. 24 is a sectional view illustrating a configuration of a piezoelectric device according to a first modification of the second preferred embodiment of the present invention. In FIG. 24, the piezoelectric device is illustrated in the sectional view the same as FIG. 15. As illustrated in FIG. 24, in a piezoelectric device 200a according to the first modification of the second preferred embodiment of the present invention, when viewed in the direction orthogonal or substantially orthogonal to the first main surface 211, a position of a portion, of the piezoelectric membrane 132, swelling the most on the side opposite to the recess 213 side and a position of a portion, of the lower electrode layer 250, swelling the most on the recess 213 side are located while being displaced from each other.

FIG. 25 is a sectional view illustrating a configuration of a piezoelectric device according to a second modification of the second preferred embodiment of the present invention. In FIG. 25, the piezoelectric device is illustrated in the sectional view the same as FIG. 15. As illustrated in FIG. 25, in a piezoelectric device 200b according to the second modification of the second preferred embodiment of the present invention, a hole 270 that extends from the bottom of the recess 213 to the second main surface 212 of the base 210 is provided in the base 210.

When viewed in the direction orthogonal or substantially orthogonal to the first main surface 211, the area of the hole 270 is smaller than the area of the membrane Mb. As a result, a significant decrease in the rigidity of the base 210 due to providing of the hole 270 can be reduced or prevented.

When viewed in the direction orthogonal or substantially orthogonal to the first main surface 211, the diameter of the hole 270 is, for example, equal to or less than about 140 µm. The hole 270 can be formed, for example, by DRIE or the like. As a result, intrusion of water or a foreign substance into the recess 213 from outside the piezoelectric device 200b through the hole 270 can be reduced or prevented. When viewed in the direction orthogonal or substantially orthogonal to the first main surface 211, the area of the hole 270 and the area of the membrane Mb may be the same or substantially the same.

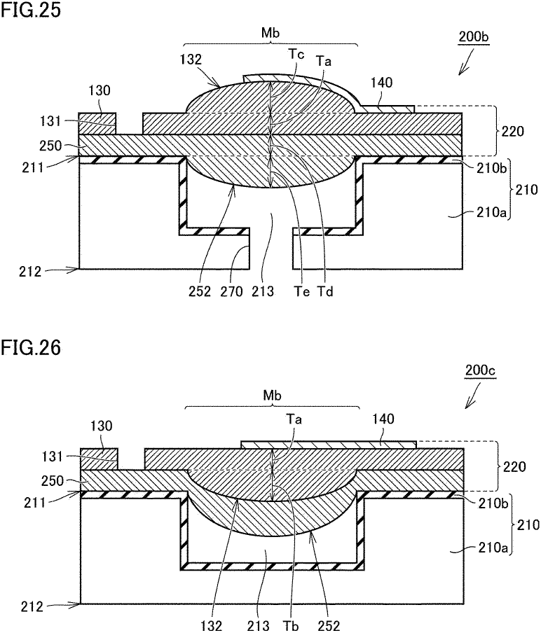

FIG. 26 is a sectional view illustrating a configuration of a piezoelectric device according to a third modification of the second preferred embodiment of the present invention. In FIG. 26, the piezoelectric device is illustrated in the sectional view the same as FIG. 15. As illustrated in FIG. 26, in a piezoelectric device 200c according to the third modification of the second preferred embodiment of the present invention, the piezoelectric membrane 132 swells on the recess 213 side. The upper surface of the piezoelectric membrane 132 is a flat surface.

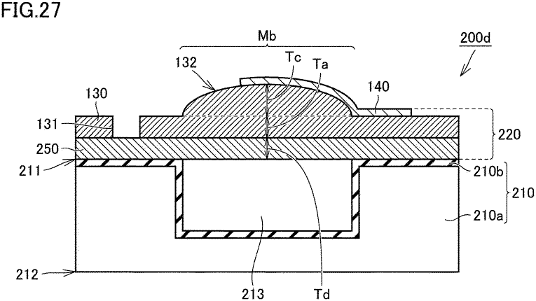

FIG. 27 is a sectional view illustrating a configuration of a piezoelectric device according to a fourth modification of the second preferred embodiment of the present invention. In FIG. 27, the piezoelectric device is illustrated in the sectional view the same as FIG. 15. As illustrated in FIG. 27, in a piezoelectric device 200d according to the fourth modification of the second preferred embodiment of the present invention, the lower electrode layer 250 has a flat plate shape. The pressure inside the recess 213 is atmospheric pressure or positive pressure.

In the description of the above-described preferred embodiments, configurations that can be combined may be mutually combined.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric device comprising:
a base including a first main surface, a second main surface on a side opposite to the first main surface, and a recess on the first main surface; and
a laminated portion laminated on a side of the first main surface of the base and covering the recess from above; wherein
the laminated portion includes, at least above the recess, a piezoelectric layer and a pair of electrode layers to apply a voltage to the piezoelectric layer, and a membrane covering the recess; and
the membrane includes a piezoelectric membrane, in the piezoelectric layer, that swells on at least one of a side of the recess and a side opposite to the side of the recess.

2. The piezoelectric device according to claim 1, wherein the piezoelectric layer is defined by a piezoelectric single-crystal body.

3. The piezoelectric device according to claim 1, wherein the piezoelectric membrane includes a portion swelling on the side of the recess and a surface of the portion swelling on the side of the recess is a curved surface.

4. The piezoelectric device according to claim 1, wherein the piezoelectric membrane has a thickness dimension that increases as a swelling height dimension of the piezoelectric membrane increases.

5. The piezoelectric device according to claim 1, wherein the recess includes a sealed space.

6. The piezoelectric device according to claim 5, wherein the recess has negative pressure.

7. The piezoelectric device according to claim 1, wherein the base includes a hole extending from a bottom of the recess to the second main surface of the base.

8. The piezoelectric device according to claim 1, wherein the base includes Si.

9. The piezoelectric device according to claim 1, wherein the pair of electrode layers include an upper electrode layer on an upper surface of the piezoelectric layer and a lower electrode layer on a lower surface of the piezoelectric layer.

10. The piezoelectric device according to claim 1, wherein the piezoelectric membrane includes a portion that swells on the side of the recess and a portion that swells on the side opposite to the side of the recess.

11. The piezoelectric device according to claim 10, wherein each of the portion that swells on the side of the recess and the portion that swells on the side opposite to the side of the recess is a curved surface.

12. The piezoelectric device according to claim 3, wherein portions of the piezoelectric membrane excluding the portion swelling on the side of the recess have a flat plate shape.

13. The piezoelectric device according to claim 11, wherein portions of the piezoelectric membrane excluding the portion that swells on the side of the recess and the portion that swells on the side opposite to the side of the recess have a flat plate shape.

14. The piezoelectric device according to claim 1, wherein the portion swelling on the side of the recess have a flat plate shape swells a maximum amount a center or approximate center of the recess.

15. The piezoelectric device according to claim 1, wherein the piezoelectric layer includes lithium tantalate or lithium niobate.

16. The piezoelectric device according to claim 9, wherein each of the upper and lower electrode layers includes Al or Pt.

17. The piezoelectric device according to claim 9, wherein an intermediate layer covers the lower electrode layer from below and a portion of the lower surface of the piezoelectric layer not covered by the lower electrode layer.

18. The piezoelectric device according to claim 17, wherein the intermediate layer includes SiO₂.

19. The piezoelectric device according to claim 17, wherein
a portion of the intermediate layer covering the recess has a curved shape; and
a portion of the intermediate layer not covering the recess has a flat plate shape.

20. The piezoelectric device according to claim 1, wherein the recess has a rectangular or substantially rectangular external shape when viewed in a direction orthogonal or substantially orthogonal to the first main surface.
